(19) United States
(12) Patent Application Publication
(10) Pub. No.: US 2011/0121280 A1
(43) Pub. Date: May 26, 2011

(54) SUBSTRATE, CONDUCTIVE PATTERN FORMATION PROCESS AND ORGANIC THIN FILM TRANSISTOR

(75) Inventor: Takeshi Hakii, Sagamihara-shi (JP)

(73) Assignee: Konica Minolta Holdings, Inc., Tokyo (JP)

(21) Appl. No.: 13/054,846

(22) PCT Filed: Jul. 17, 2009
(86) PCT No.: PCT/JP2009/062963

§ 371 Date: Jan. 19, 2011

(30) Foreign Application Priority Data
Jul. 24, 2008 (JP) 2008-190797

(51) Int. Cl. H01L 51/30; H01L 51/40

(52) U.S. Cl. 257/40; 438/99; 257/E51.046

(57) ABSTRACT

The present invention provides a substrate with excellent thin line reproducibility and excellent adhesion with conductive wiring, a conductive pattern formation process employing the substrate and an organic thin film transistor employing the substrate. The substrate is characterized in that it has a sensitizing dye and a compound represented by the following formula (I):

(R)ₙ-—i(A)₃₋ₙ-(B) Formula (I)

wherein R represents an alkyl group having a carbon atom number of not more than 8; A represents an alkoxy group or a halogen atom; B represents a substituent containing an SH group; and n is an integer of from 0 to 2.

### FIELD OF THE INVENTION

The present invention relates to a novel substrate, a conductive pattern formation process employing the substrate, and an organic thin film transistor employing the substrate.

### TECHNICAL BACKGROUND

In order to produce an electronic circuit with a precious conductive pattern, a photolithographic method has been carried out in which a resist layer is provided on a substrate with a conductive layer, exposed to light through a mask with an intended pattern, and then developed to remove any unnecessary resist layer. However, the photolithographic method requires many processing steps, which is complicated and costly. Further, the method has problems in that disposal of the removed resist layer is a burden on the environment.

In order to solve the above problems, a method has been investigated which comprises forming a monomolecular film composed of a long chain alkyl type silane coupling agent on a substrate, pattern exposing the film through a Xe excimer lamp to decompose a part of the monomolecular film, where portions at which the monomolecular film remains and portions at which the monomolecular film is decomposed are formed, and difference of adhesion to a metal is produced between the two portions, and employing the difference (see, for example, Patent Document 1 below).

The present inventor has made an extensive study on the above method, and as a result, it has been found that the method proposed in Patent Document 1 has the advantage in that a vacuum process is not required, however, it has problems in that it requires a light with a wavelength less than 300 nm to decompose a monomolecular film, which imposes many limitations to the apparatus employed, and has adverse effects on necessary materials, and causes adhesion lowering or undesired variation of other characteristics.

In recent years, an organic thin film transistor (organic TFT, i.e., Organic Thin Film Transistor OTFT) draws attention as a next generation flat panel display device with high quality and low price or a switching element for driving pixels on an electronic paper.

An organic thin film transistor has substantially the same structure as a silicon thin film transistor, but is different from a silicon thin film transistor in that it employs an organic substance in the semiconductor active layer. The organic thin film transistor can be manufactured without employing a vacuum apparatus according to an ink jet method or a printing method, and therefore, the organic thin film transistor can be manufactured simply and at low cost as compared with a silicon TFT. The organic thin film transistor has advantages that it is suitably applied to an electronic circuit board which is not broken by impact, and can be bent and folded. An organic thin film transistor having such advantages is useful in the case where an element with a wide area is manufactured, a low temperature manufacturing condition is required or a product with high resistance to folding is required, and is desired as an element for driving a matrix of a large size display or an element for driving an organic EL or an electronic paper. Many companies have developed these organic thin film transistors.

Operation principle of an organic thin film transistor is to control resistance by voltage. The gate voltage being controlled, the insulating layer works to generate an accumulation layer in a carrier at the contact interface between the organic semiconductor layer and the insulating layer, whereby current between the two ohm contacts is controlled.

Conventionally, the source electrode, the drain electrode, the gate electrode, the contact electrode or the pixel electrode of an organic thin film transistor has been formed by a vacuum process such as a sputtering method, resulting in cost increase due to the vacuum process. An ink jet method (see Patent Document 2 below) or a screen printing method (see Patent Document 3 below) have been investigated as an electrode formation method without employing the vacuum process.

Techniques disclosed in the Patent Documents described above have been studied in detail. As a result, it has been found that in the method disclosed in the Patent Document 2, in which a source electrode and a drain electrode are formed via an ink jet method, controlling affinity of ink to a substrate, additives in the ink remain in the electrodes, which adversely affects transistor performance.

It has also been found that the method disclosed in the Patent Document 3, which forms a source electrode and a drain electrode via a screen printing method employing a silver paste, does not provide source and drain electrode with high resolution nor a transistor with high speed and low power consumption.

Prior Art

Patent Documents

Patent Document 1: Japanese Patent O.P.I. Publication No. 2005-216907

Patent Document 2: Japanese Patent O.P.I. Publication No. 2003-318190

Patent Document 3: Japanese Patent O.P.I. Publication No. 2005-72188

### DISCLOSURE OF THE INVENTION

### Problems to be Solved by the Invention

The present invention has been made in view of the above. An object of the invention is to provide a substrate with excellent thin line reproducibility and excellent adhesion with conductive wiring, a conductive pattern formation process employing the substrate and an organic thin film transistor employing the substrate.

### Means for Solving the Above Problems

The above object of the invention can be attained by the following constitutions.

1. A substrate having a sensitizing dye and a compound represented by the following formula (I):

(R)ₙ—Si(A)₃₋ₙ-(B) Formula (I)

wherein R represents an alkyl group having a carbon atom number of not more than 8; A represents an alkoxy group or a halogen atom; B represents a substituent containing an SH group; and n is an integer of from 0 to 2.

2. The substrate of item 1 above, wherein the compound represented by formula (I) above has a triazine ring.

3. The substrate of item 1 or 2 above, wherein an absorption maximum wavelength of the sensitizing dye is from 300 to 600 nm.

4. The substrate of any one of items 1 through 3 above, wherein the substrate has a layer containing the sensitizing dye and a layer containing the compound represented by formula (I) above.

5. The substrate of item 4 above, wherein the layer containing the sensitizing dye further contains a polymerization initiator.

6. The substrate of item 4 or 5 above, wherein the layer containing the sensitizing dye further contains a binder polymer.

7. A process for forming a conductive pattern employing the substrate of any one of items 1 through 6 above, the process comprising an exposing step and a plating treatment step.

8. The process for forming a conductive pattern of item 7 above, wherein the exposing step is carried out employing a light having the main wavelength in the range of from 300 to 600 nm.

9. The process for forming a conductive pattern of item 7 or 8 above, wherein a high pressure mercury lamp is used at the exposing step.

10. The process for forming a conductive pattern of any one of items 7 through 9 above, wherein the plating treatment step comprises a step of providing a catalyst and a step of carrying out electroless plating treatment.

11. An organic thin film transistor, wherein the transistor has the substrate of any one of items 1 through 6 above.

12. The organic thin film transistor of item 11 above, wherein a conductive pattern is formed employing the process for forming a conductive pattern of any one of items 7 through 10 above.

13. The organic thin film transistor of item 12 above, wherein the conductive pattern is a source electrode or a drain electrode.

### EFFECTS OF THE INVENTION

The present invention can provide a substrate with excellent thin line reproducibility and excellent adhesion with conductive wiring, a conductive pattern formation process employing the substrate and an organic thin film transistor employing the substrate.

### BRIEF EXPLANATION OF THE DRAWING

FIG. 1 is a sectional view showing one embodiment of a structure of the organic thin film transistor of the invention.

### PREFERRED EMBODIMENT OF THE INVENTION

Next, the present invention will be explained in detail.

The substrate of the invention is characterized in that it comprises a compound represented by formula (I) and a sensitizing dye. Use of the substrate of the invention can form a conductive pattern according to a simple process.

[Conductive Pattern]

The conductive pattern in the invention is characterized in that it is formed employing a substrate comprising a compound represented by formula (I) and a sensitizing dye.

The substrate of the invention comprises a layer containing a compound represented by formula (I) and a layer containing a sensitizing dye. The layer containing a compound represented by formula (I) and layer containing a sensitizing dye are preferably adjacent to each other. The binder or a polymerization initiator may be optionally added to the layer from the viewpoints of layer durability or exposure energy reduction.

The conductive pattern formation process of the invention is characterized in that the process comprises bringing a base material into contact with a solution of the compound represented by formula (I), whereby the compound represented by formula (I) combines with the base material through a siloxane bond.

A solvent used in a solution containing the compound represented by formula (I) may be any solvent such as water, a water based solvent or an organic solvent, as long as it dissolves the compound represented by formula (I). As the solvent, an alcoholic solvent is preferred, and ethanol or isopropanol is more preferred in view of handling and drying properties.

As a method of pre-processing the base material to be brought into contact with a solution containing the compound represented by formula (I), there is mentioned a known processing method such as cleaning by alcohol, cleaning by an acid or alkaline solution, cleaning by a surfactant solution, an atmospheric pressure plasma treatment or UV/ozone treatment. The pre-processing method is preferably a method in which cleaning by an alkaline solution, which is followed by UV/ozone treatment, is carried out.

The conductive pattern formation process of the invention is characterized in that the compound represented by formula (I) is combined with a base material through a siloxane bond, and then a layer containing a sensitizing dye is formed. As a method of forming a layer containing a sensitizing dye, there is mentioned an ink jet method, a printing method, a dipping method, a spin coat method, each method employing a solution containing a sensitizing dye. A binder or a polymerization initiator can be added to the solution containing a sensitizing dye as necessary. The thickness of the layer is preferably from 1 to 100 nm.

It is preferred in the conductive pattern formation process of the invention that a layer containing the compound represented by formula (I) and a sensitizing dye is exposed to light having a maximum wavelength in the range of from 300 to 600 nm, whereby areas capable of combining with a metal and areas incapable of combining with a metal are formed to separate from each other. It is preferred that the layer exposed to light is brought into contact with a solution containing a metal to combine the metal with the areas capable of combining with a metal. It is preferred that the layer exposed to light is brought into contact with a solution containing a metal, followed by plating treatment to selectively form a plating film at exposed portions.

The separation of exposed portions from unexposed portions may be carried out by light exposure through a photomask or by pattern exposure employing a scanning laser light.

The conductive pattern formation process of the invention is characterized in that a metal containing solution is brought into contact with a substrate after light exposure above, whereby the metal is combined with areas capable of combining with a metal. The metal containing solution may be any solution as long as it is a solution, in which a metal ion is dissolved, and is preferably a solution containing gold, silver, copper, chromium or palladium.

In the conductive pattern formation process of the invention, a method is one of the preferred embodiments in which the substrate having a metal combining with areas capable of combining with a metal is subjected to plating treatment, whereby a plating film is selectively formed at exposed areas. In this plating treatment, plating can be carried out at areas selectively separated by light exposure to be plated which can eliminate troublesome treatments such as photolithography necessary to form a plate pattern and can form a plate pattern simply and in a short time. An anchor portion is combined through an —O—Si group, which can provide a plating film with good adhesion strength.

According to the method as described above, a metal electrode with an intended pattern can be prepared according to plating treatment.

[Compound Represented by Formula (I)]

In Formula (I) above, R is an alkyl group having a carbon atom number of not more than 8, and is preferably a lower alkyl group having a carbon atom number of from 1 to 4; n is an integer of from 0 to 2; A represents an alkoxy group or a halogen atom; in which examples of the alkoxy group include a lower alkoxy group (having a carbon atom number of from 1 to 4) such as a methoxy group, an ethoxy group, a propoxy group or a butoxy group, and the alkoxy group is preferably a methoxy group or an ethoxy group, and the halogen atom is preferably a chlorine atom; and B represents a substituent containing an SH group. Although B is not specifically limited, B may be any as long as it is an aliphatic or (hetero) aromatic group containing at least one mercapto group and preferably at least two mercapto groups.

Examples thereof include the following compounds.

(A-1) Triethoxysilyl-propylamino-triazine-dithiol

(A-2) γ-Mercaptopropyl-trimethoxysilane

(A-3) γ-Mercaptopropylmethyldimethoxysilane

(A-4) Mercaptopropyltriethoxysilane

(A-5) γ-Mercaptopropyltrichlorosilane

Among compounds represented by formula (I) above, a compound having a triazine ring is especially preferred. For example, (A-1) triethoxysilyl-propylamino-triazine-dithiol can be easily prepared by condensation reaction of γ-propyltriethoxysilane with a corresponding mercaptoamine, in this case, 1-amino-3,5-dimercaptotriazine (as disclosed in Japanese Patent O.P.I. Publication No. 2001-316872).

[Sensitizing Dye]

Examples thereof include the following compounds.

The sensitizing dye in the invention may be any compound as long as it can shift spectral sensitivity of the compound represented by formula (I) to the long wavelength side. Examples of the sensitizing dye include phthalein dyes, cyanine dyes, hemicyanine dyes, styryl dyes, merocyanine dyes, triphenylmethane dyes, xanthene dyes, oxonol dyes, cumarin dyes and acridone dyes. The cumarin dyes and acridone dyes are preferred as the sensitizing dye in the invention.

Next, typical examples of the sensitizing dye in the invention will be listed, but the invention is not specifically limited thereto.

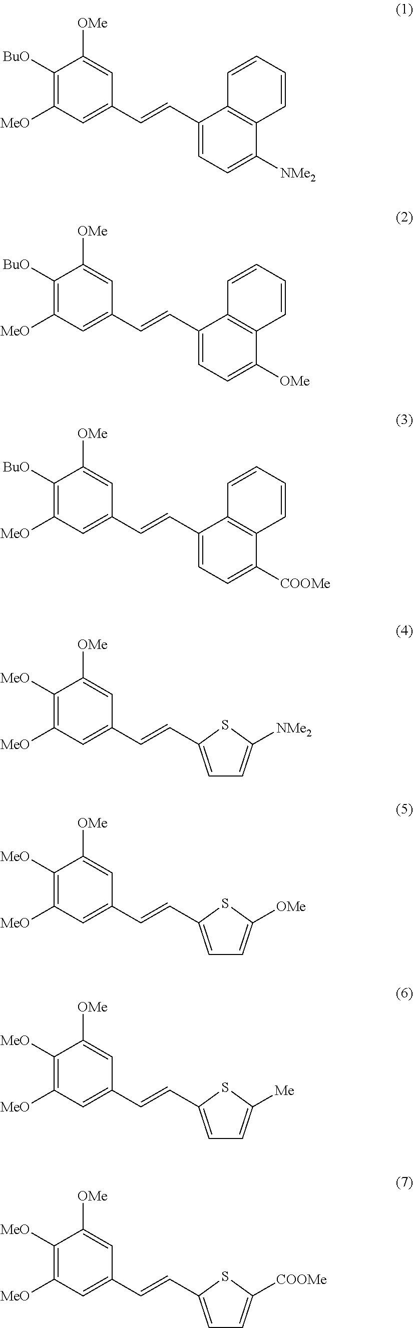

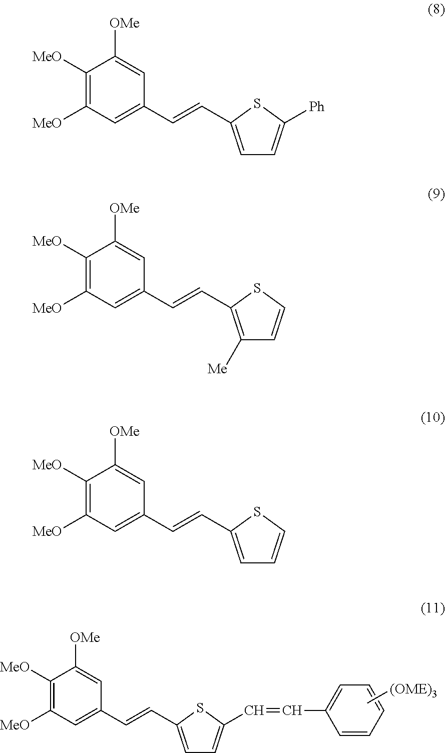

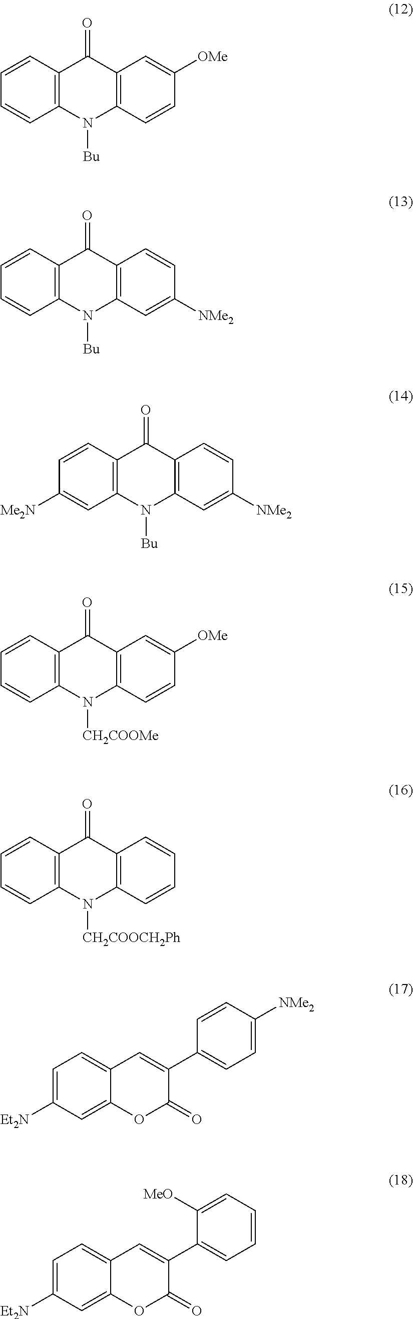

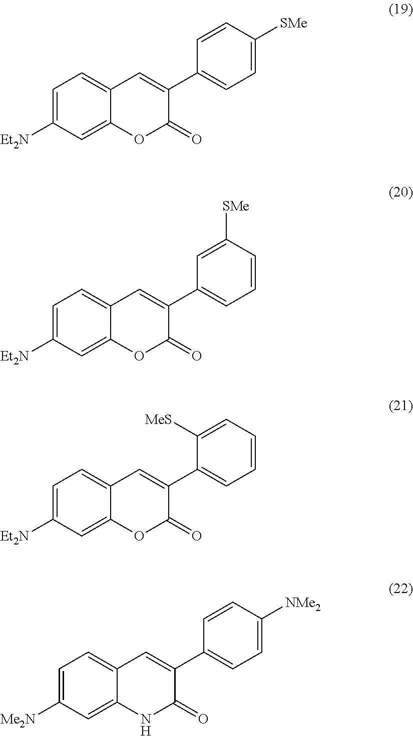

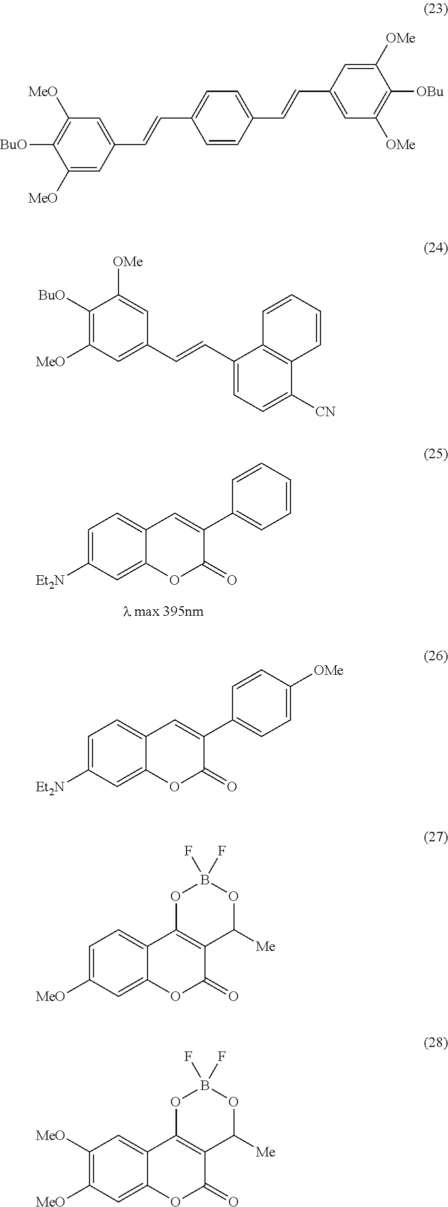

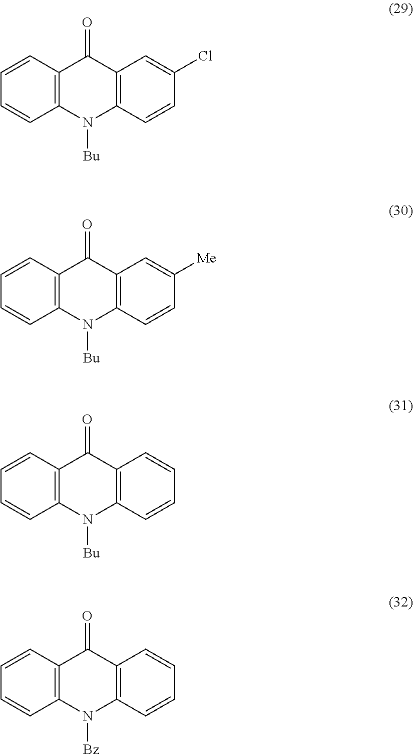

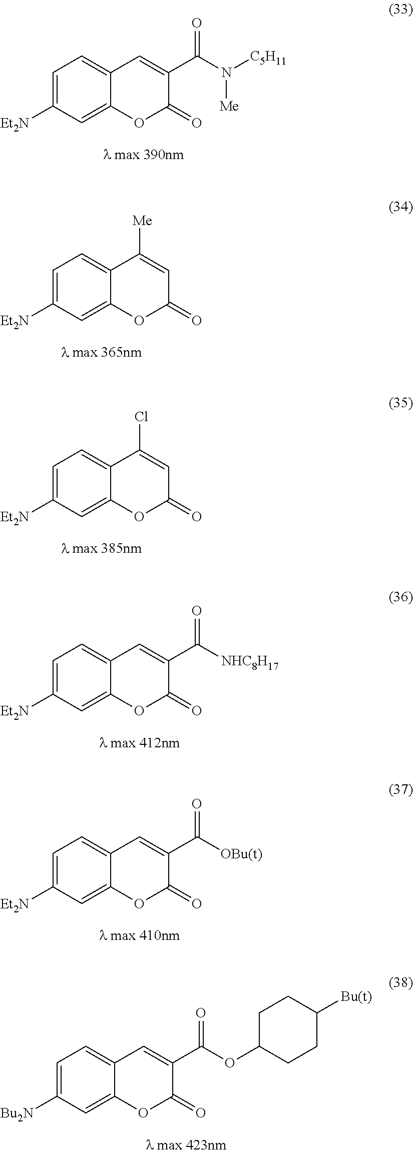

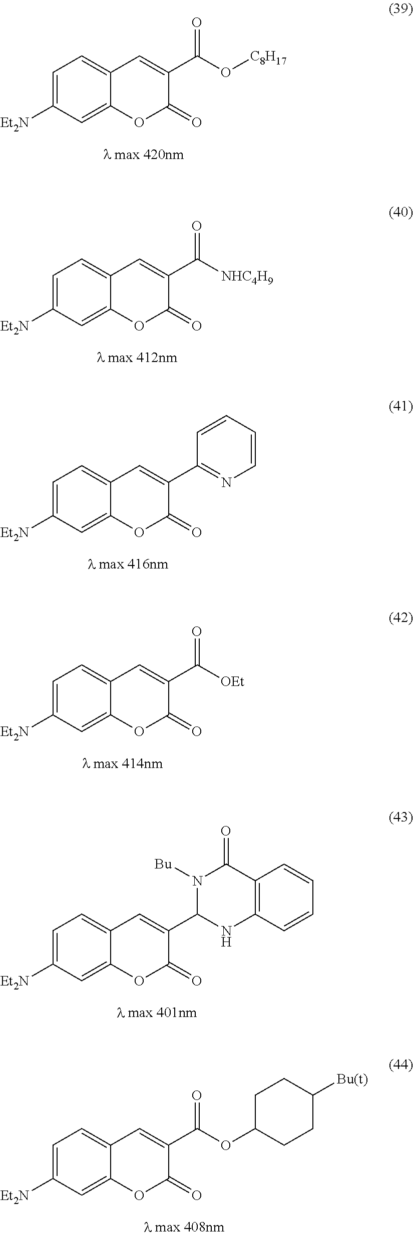

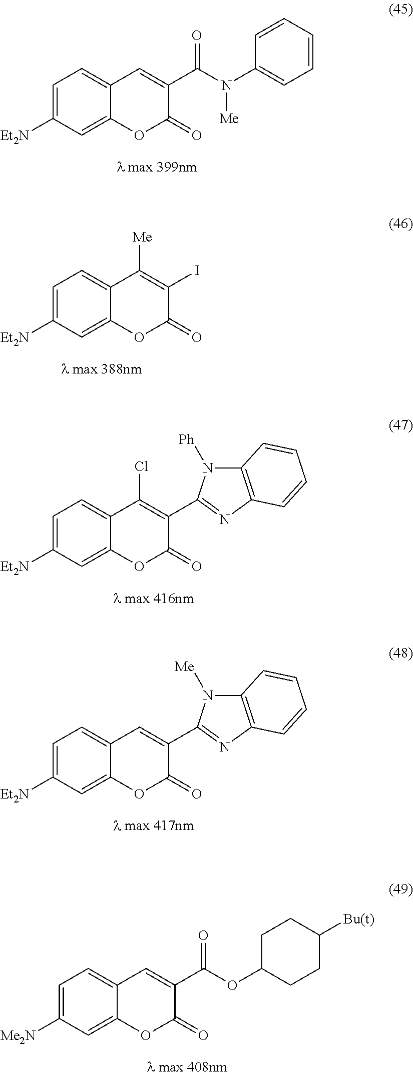

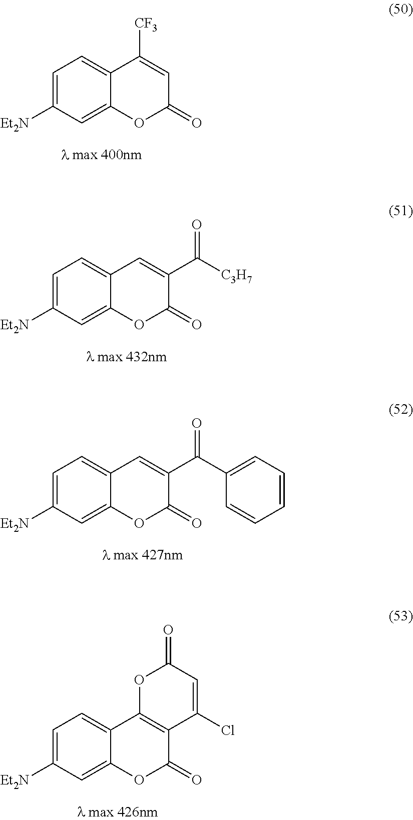

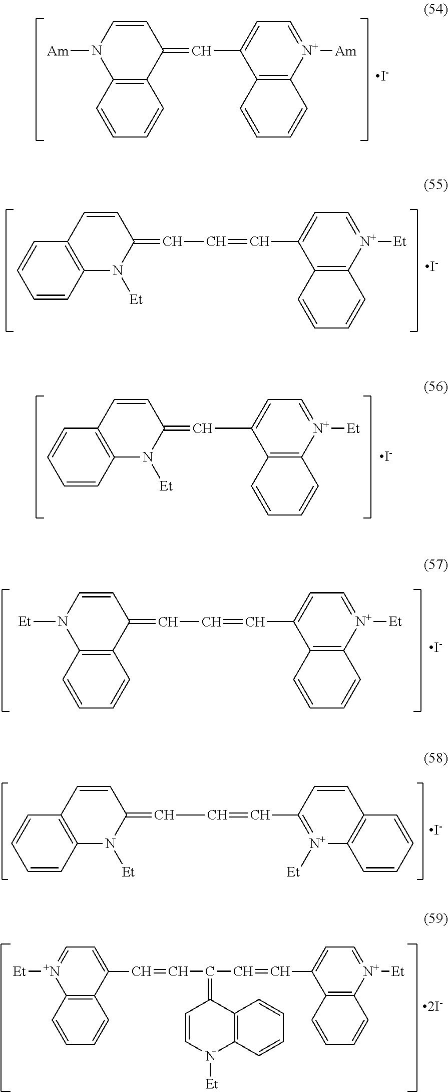

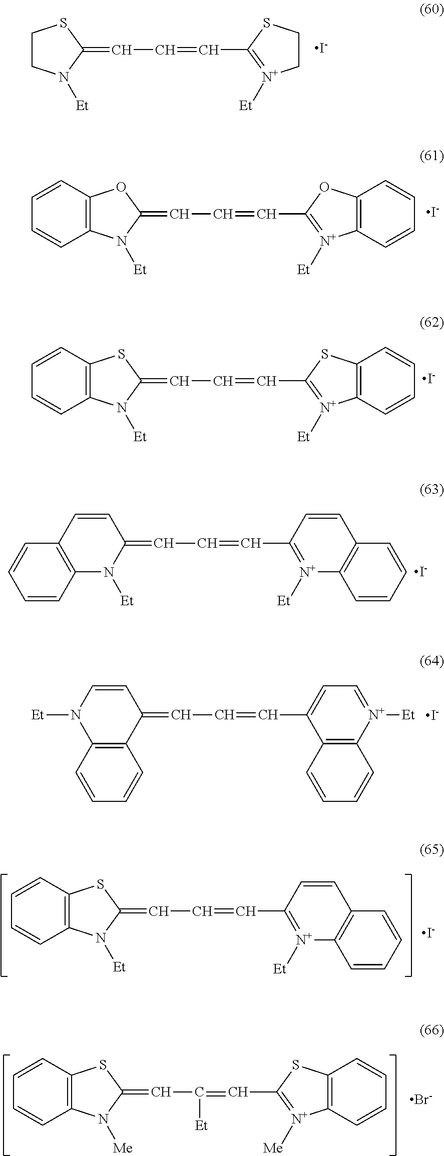

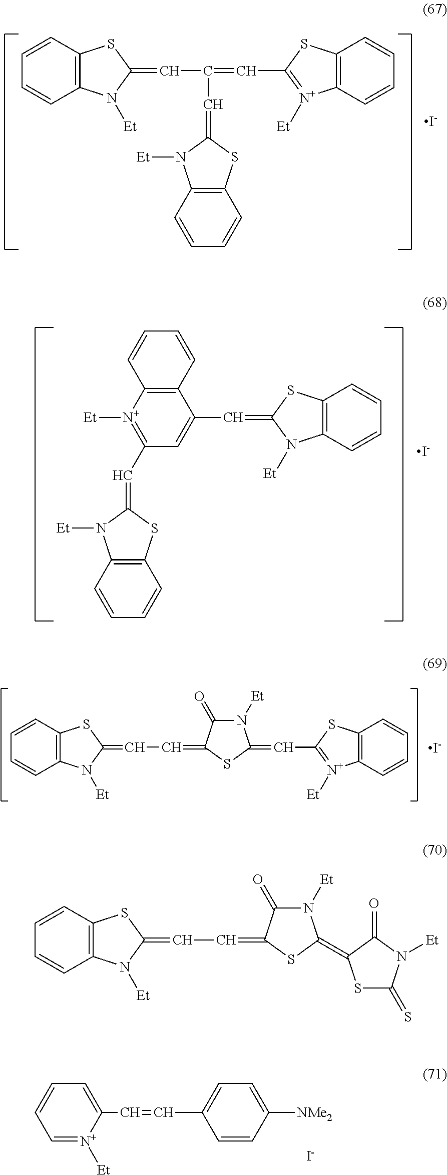

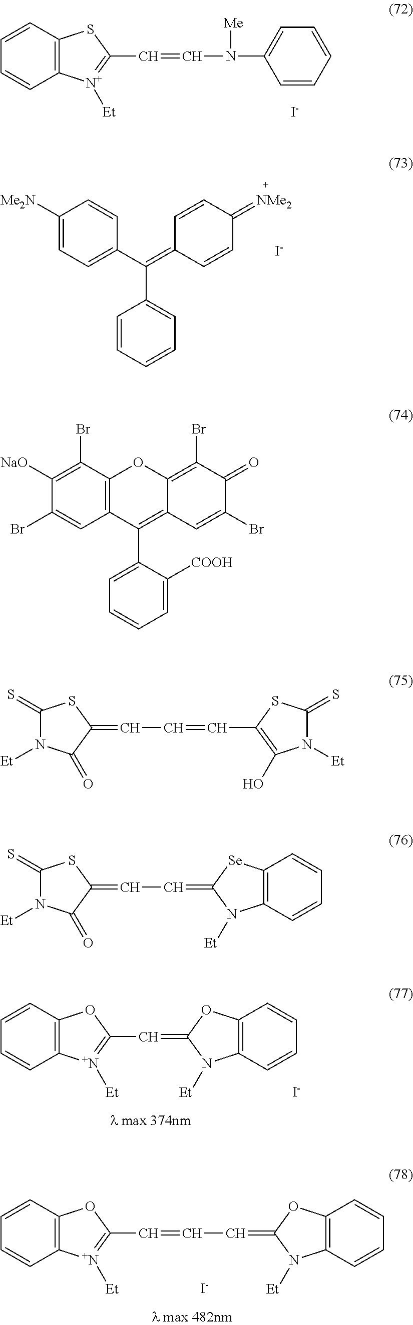

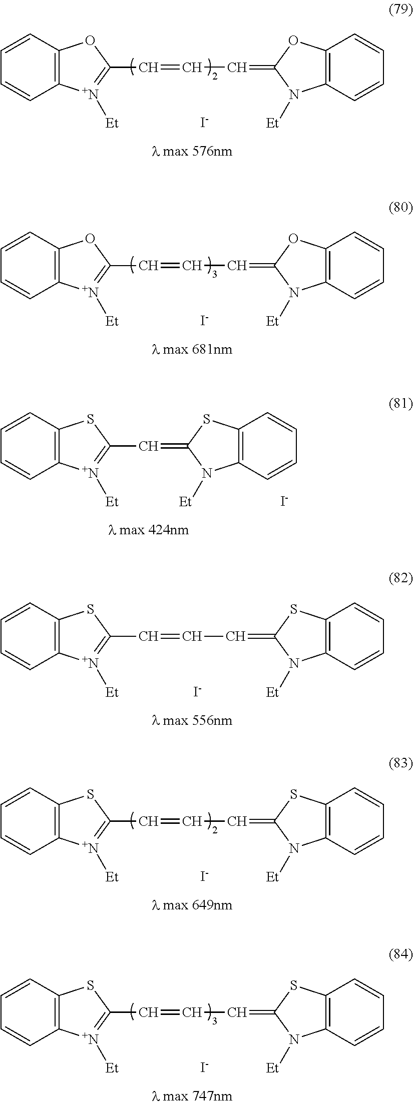

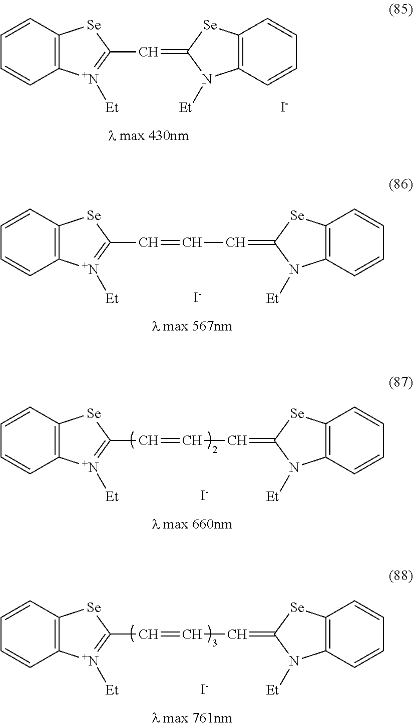

It is preferred that the sensitizing dye in the invention has absorption maximum wavelength in the range of from 300 nm to 600 nm. The absorption maximum wavelength of each of the compounds described above was determined from the absorption spectra of an acetonitrile solution containing 1 mmol/liter of the compound.

The absorption maximum wavelength is determined in the state in which the compound is dissolved in a solvent. Any solvent can be employed without any limitations as long as the solvent can dissolve the compound to be measured. When a water soluble compound is measured, water or a mixture of water and ethanol is employed as a solvent, and when an oil soluble compound is measured, acetonitrile, toluene or a mixture thereof is employed as a solvent. The concentration of the compound in the solution is not specifically limited as long as the absorption maximum wavelength is confirmed. The concentration of a compound having larger absorption in the solution may be less.

[Substrate]

As the substrate used in the present invention, there are preferably employed synthetic plastic films including polyolefins such as polyethylene or polypropylene, polycarbonates, cellulose acetate, polyethylene terephthalate, polyethylene dinaphthalene carboxylate, polyethylene naphthalates, polyvinyl chloride, polyimides, polyvinyl acetals, and polystyrene.

Polystyrenes having a syndiotactic structure are also preferably employed. These can be obtained according to the methods described, for example, in Japanese Patent O.P.I. Publication Nos. 62-117708, 1-46912, and 1-178505. Further, there are mentioned metallic substrates such as stainless steel, paper supports such as baryta paper or resin-coated paper, supports prepared by forming a reflection layer on a plastic film as described above, and those described as supports in Japanese Patent O.P.I. Publication No. 62-253195 (pages 29-31). Also, there are preferably employed those described on page 28 of RD No. 17643, on page 647, the right column to page 648, the left column of RD No. 18716, and on page 879 of RD, No. 307105. As these supports, usable are those in which curling tendency is minimized realized via thermal treatment at a temperature of at most Tg as described in U.S. Pat. No. 4,141,735.

Further, the surface of any of these supports may be surface-treated to enhance adhesion between the support and other constituent layers. In the present invention, glow discharge treatment, UV irradiation treatment, corona treatment, and flame treatment can be employed for such surface treatment. Further, the supports described on pages 44-149 of Kochi Gijutsu (Known Techniques), No. 5 (issued on Mar. 22, 1991, published by Aztech Corp.) can be used. Still further, there are exemplified those described on page 1009 of RD, No. 308119 and in the section of “Supports” of Product Licensing Index, Vol. 92, page 108. In addition, glass substrates, and glass-incorporated epoxy resins can be employed.

[Polymerization Initiator]

In the polymerization initiator in the invention, electrons excited in the sensitizing dye are transferred to a compound represented by formula (I) through the polymerization initiator, whereby exposure energy is reduced. The polymerization initiator may be any compound as long as it can generate radicals. Examples thereof include a bisimidazole compound and titanocene compound.

[Binder Polymer]

In the invention, as a binder polymer in the layer containing a sensitizing dye, there are mentioned natural compounds such as protein, for example, gelatin and gelatin derivatives or polysaccharides, for example, cellulose derivatives, starch, gum arabic, dextrane, pullulan, carrageenan; and synthetic polymers such as polyvinyl alcohol, polyvinyl pyrrolidone, acrylamide polymers or their derivatives. The gelatin derivatives include acetylated gelatin and phthalated gelatin. The polyvinyl alcohol derivatives include terminal alkyl group-modified polyvinyl alcohol and terminal mercapto group-modified polyvinyl alcohol. The cellulose derivatives include hydroxyethyl cellulose, hydroxypropyl cellulose and carboxymethyl cellulose. In addition, there are also usable those described in Research Disclosure and on pages 71-75 of Japanese Patent O.P.I. Publication No. 64-13546; and highly water-absorbing polymers described in U.S. Pat. No. 4,960,681 and Japanese Patent O.P.I. Publication No. 62-245260, that is, homopolymers of vinyl monomers containing —COOM or —SO₃ M (M is a hydrogen atom or an alkali metal) and copolymers of these monomers or of the same and other monomers (e.g., sodium methacrylate, ammonium methacrylate, and potassium acrylate). Two or more kinds of these binders can be used in combination.

[Exposure Step]

When exposure is carried out in the pattern form in the exposure step in the invention, a compound represented by Formula (I) is selectively oxidized or decomposed only at exposed portions, thereby producing difference in adhesion to a metal between exposed portions and unexposed portions. The difference can form a metal wiring pattern, and a conductive pattern with high precision and high adhesion.

The exposure steps in the invention include exposure through a quartz glass plate with a pattern of a metal such as chromium, reduction projection exposure employing a lens or a mirror, and direct imaging employing electron beams and the like.

The exposure step in the invention is characterized in that exposure is carried out employing a light source with a main wavelength of from 300 nm to 600 nm. A light source with a main wavelength of shorter than 300 nm deteriorates a substrate, which results in conductive pattern deterioration or undesired property variation of other functional materials employed. Examples of a light source with an absorption maximum wavelength of from 300 nm to 600 nm include a high pressure mercury lamp.

[Plating Treatment Step]

In the invention, conventional plating treatments can be applied, but among them, an electroless plating method is preferably applied which can easily provide a conductive pattern with a low electrical resistance without complex steps and at low cost.

The plating treatment via the electroless plating method is one in which a plating agent is brought into contact with a conductive pattern comprising metal microparticles working as a plating catalyst. Thus, the plating agent being brought into contact with the metal microparticles as the plating catalyst, electroless plating is carried out on portions at which the conductive pattern is to be formed, thereby obtaining superior conductivity.

As a plating agent used in the plating treatment in the invention, there is utilized, for example, a solution, in which an ion of a metal to be deposited as a plating material is homogeneously dissolved and a reducing agent is contained in combination with a metal salt. Herein, a plating agent used is ordinarily a solution but is not limited thereto as long as it is capable of inducing electroless plating, and a gaseous plating agent or a powder plating agent may also be used

Typical examples of the metal salt include halides, nitrates, sulfates, phosphates, borates, acetates, tartarates or citrates of at least one metal selected from Au, Ag, Cu, Ni, Co and Fe. Typical examples of the reducing agent include hydrazine, hydrazine salts, borohalides, hypophosphites, hyposulfites, alcohols, aldehydes, carboxylic acids, and carboxylates. Herein, any element such as boron, phosphor or nitrogen contained in the reducing agent may be contained in an electrode to be deposited. Further, an alloy may be formed from a mixture of the metal salts.

As the plating agent, a mixture of the metal salt and the reducing agent may be applicable, and the metal salt or the reducing agent may be applicable individually, also. Herein, in order to form an electrode pattern more sharply, a mixture of the metal salt and the reducing agent is preferably applied. Further, when the metal salt or the reducing agent is applied individually, the metal salt is initially applied on a portion where the electrode is formed, and then the reducing agent is applied to the portions where the metal salt has been applied, resulting in formation of a more stable electrode pattern.

The plating agent may contain additives such as a buffering agent for pH control or a surfactant, as necessary. Further, an organic solvent other than water such as alcohol, ketone or ester may be added as a solvent used for the solution.

A composition of the plating agent is composed of a salt of a metal to be deposited, a reducing agent, and optionally an additive or an organic solvent, and the concentration and the composition may be adjusted depending on the deposition rate. The deposition rate may also be adjusted by controlling the temperature of the plating agent. Methods to control this temperature include a method in which the temperature of the plating agent is controlled and a method in which when a substrate is immersed in the plating agent, the temperature is controlled by heating or cooling a substrate before the immersion. The film thickness of a metal thin film to be deposited may also be adjusted via a period during which the substrate is immersed in the plating agent.

[Organic Thin Film Transistor]

The organic thin film transistor of the invention is characterized in that it is formed employing a substrate comprising a compound represented by formula (1) and a sensitizing dye.

In the invention, it is preferred that at least one electrode selected from a pixel electrode, a source electrode, a drain electrode, a gate electrode and a contact electrode is formed from a layer composed of the compound represented by formula (I), a layer composed of the sensitizing dye and a layer composed of a metal.

The organic thin film transistor manufacturing process of the invention is characterized in that the process comprises bringing a base material into contact with a solution of the compound represented by formula (I), whereby the compound represented by formula (I) combines with the base material through a siloxane bond.

A solvent used in a solution containing the compound represented by formula (I) may be any solvent such as water, a water based solvent or an organic solvent, as long as it dissolves the compound represented by formula (I). As the solvent, an alcoholic solvent is preferred, and ethanol or isopropanol is more preferred in view of handling and drying properties.

As a method of pre-processing an electrode to be brought into contact with a solution containing the compound represented by formula (I), there is mentioned a known processing method such as cleaning by alcohol, cleaning by an acid or alkaline solution, cleaning by a surfactant solution, an atmospheric pressure plasma treatment or UV/ozone treatment. The pre-processing method is preferably a method in which cleaning by an alkaline solution, which is followed by UV/ozone treatment, is carried out.

The organic thin film transistor manufacturing process of the invention is characterized in that the compound represented by formula (I) is combined with a base material through a siloxane bond, and then a layer containing a sensitizing dye is formed. As a method of forming a layer containing a sensitizing dye, there is mentioned an ink jet method, a printing method, a dipping method, a spin coat method, each method employing a solution containing a sensitizing dye. A binder or a polymerization initiator can be added to the solution containing a sensitizing dye as necessary.

It is preferred in the organic thin film transistor manufacturing process of the invention that a layer containing the compound represented by formula (I) and a sensitizing dye is exposed to light having a maximum wavelength in the range of from 300 to 600 nm, whereby areas capable of combining with a metal and areas incapable of combining with a metal are formed to separate from each other. It is preferred that the layer exposed to light is brought into contact with a solution containing a metal to combine the metal with the areas capable of combining with a metal. It is preferred that the layer exposed to light is brought into contact with a solution containing a metal, followed by plating treatment to selectively form a plating film at exposed portions.

That is; it is preferred that the organic thin film transistor manufacturing process of the invention comprises subjecting to light exposure a base material (substrate) combining with the compound represented by formula (I), whereby areas capable of combining with a metal and areas incapable of combining with a metal are formed to separate from each other.

The base material (substrate) herein referred to may be any material as long as it is a base material (substrate) having on the surface a group capable of reacting with alkoxysilanes and combining with them through a siloxane bond (Si—O), for example, a group such as a hydroxyl group. For example, the base material may have on the surface a layer having a group such as a hydroxyl group reacting with the alkoxysilanes or the base material itself may have a surface having such a property. Examples thereof include a base material (substrate) such as an electrode having a layer composed of a metal oxide (for example, a metal oxide such as silicon oxide).

The separation of exposed portions from unexposed portions may be carried out by light exposure through a photomask or by pattern exposure employing a scanning laser light.

The organic thin film transistor manufacturing process of the invention is characterized in that a metal containing solution is brought into contact with the substrate after the light exposure, whereby the metal is combined with areas capable of combining with a metal. The metal containing solution may be any solution as long as it is a solution, in which a metal ion is dissolved, and is preferably a solution containing gold, silver, copper, chromium or palladium.

In the organic thin film transistor manufacturing process of the invention, a method is one of the preferred embodiments in which the substrate having a metal combining with areas capable of combining with a metal is subjected to plating treatment, whereby a plating film is selectively formed at exposed areas. In this plating treatment, plating can be carried out at areas selectively separated by light exposure to be plated which can eliminate troublesome treatments such as photolithography necessary to form a plate pattern and can form a plate pattern simply and in a short time. An anchor portion is combined through an —O—Si group, which can provide a plating film with good adhesion strength. According to the method as described above, a metal electrode with an intended pattern can be prepared according to plating treatment.

[Constitution of Organic Thin Film Transistor]

Next, each of the components constituting the organic thin film transistor of the invention will be explained in detail.

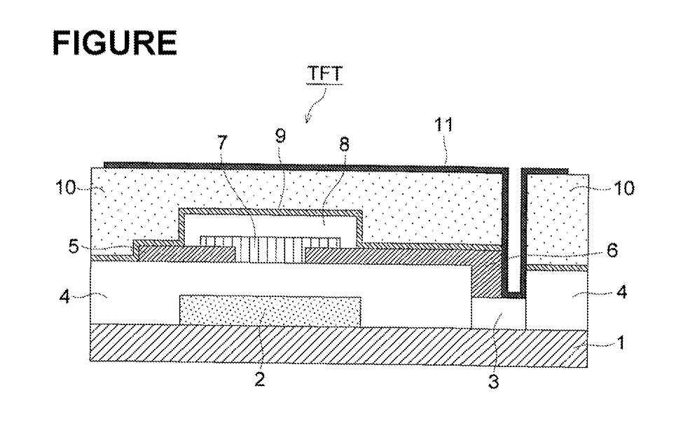

FIG. 1 is a sectional view showing one embodiment of a structure of the organic thin film transistor of the invention.

In FIG. 1, the organic thin film transistor TFT is comprised of a base plate 1, a gate electrode 2, a contact electrode 3, a source electrode 5, a drain electrode 6, and an organic semiconductor layer 7. The gate electrode 2 is provided on the base plate 1, and a gate insulation layer 4 is provided to cover the gate electrode 2. A space for forming a channel of the organic semiconductor layer 7, the source electrode 5 and the drain electrode 6 are provided on the gate insulation layer 4. The organic semiconductor layer 7 is formed at the space between the source electrode 5 and the drain electrode 6 to connect the source and drain electrodes.

Next, constitution, material and process of each component constituting the organic thin film transistor will be explained.

The base plate 1 is not specifically limited, and glass or a resin sheet such as a flexible plastic film can be employed as the base plate. Typical examples of the plastic film include polyethylene terephthalate (PET), polyethylene naphthalate (PEN), polyethersulfone (PES), polyetherimide, polyether ether ketone, polyphenylene sulfide, polyallylate, polyimide, polycarbonate (PC), cellulose triacetate (TAC), or cellulose acetate propionate (CAP). Use of such a plastic film makes it possible to decrease weight, to enhance portability, and to enhance durability against impact due to its flexibility, as compared to glass.

A material for the gate electrode 2 or the contact electrode 3 is not specifically limited as long as it is a conductive material and is preferably a material with a sufficient conductivity. Examples thereof include Al, Cr, Ag, Mo and those subjected to doping.

In order to form a gate electrode 2 or a contact electrode 3, it is necessary to form a conductive layer on a base plate 1. As a method for forming this conductive layer, there is, for example, a known vapor deposition or sputtering method which is carried out employing the materials described above. Thereafter, known photolithography treatment (coating, exposing and development of resist) and etching treatment are conducted to form a gate electrode 2.

As another method for forming a gate electrode 2 or a contact electrode 3, there is an ink jet method or a printing method such as letter press printing, intaglio printing or screen printing carried out employing fluid electrode materials.

As a conductive particle dispersion, there is a conductive particle dispersion such as a paste or ink in which conductive particles comprised of metals etc. are dispersed in water, an organic solvent or their mixture preferably in the presence of a dispersion stabilizer of an organic material. The dispersion as described above, in which a dispersion medium containing water mainly is used, is preferred, since the conductive layer is formed on an organic semiconductor layer.

Examples of metal materials (metal particles) for the conductive particles include platinum, gold, silver, cobalt, nickel, chromium, copper, iron, tin, antimony lead, tantalum, indium, palladium, tellurium, rhenium, iridium, aluminum, ruthenium, germanium, molybdenum, tungsten and zinc. Platinum, gold, silver, copper, cobalt, chromium, indium, nickel, palladium, molybdenum, and tungsten, each having a work function of not less than 4.5 eV, are especially preferred.

Further, there can preferably be utilized conductive polymers known in the art with electric conductivity enhanced via doping such as conductive polyaniline, conductive polypyrrole, conductive polythiophene or a complex (PEDOT/PSS) of polyethylenedioxy thiophene and polystyrene sulfonic acid. Among the above, those are preferred which exhibit low electrical resistance in the interface to be in contact with the semiconductor layer.

A preferred method for forming a gate electrode 2 or a contact electrode 3 is a plating treatment method conducted employing a compound represented by formula (I) in the invention. A source electrode 5, a drain electrode 6 or a pixel electrode can be formed in the same manner as described above in the gate electrode.

Materials constituting an organic semiconductor layer 7 are not specifically limited and examples thereof include various condensed polycyclic aromatic compounds or conjugated compounds. Examples of the condensed polycyclic aromatic compounds include compounds such as anthracene, tetracene, pentacene, hexacene, heptacene, phthalocyanine and porphyrin, and their derivatives or mixtures.

Examples of the conjugated compounds include polythiophene and oligomers thereof, polypyrrole and oligomers thereof, polyaniline, polyphenylene and oligomers thereof, polyphenylene vinylene (PPV) and oligomers thereof, polyethylene vinylene and oligomers thereof, polyacetylene, polydiacetylene, tetrathiafluvalene compounds, quinone compounds, cyano compounds such as tetracyanoquinodimethane, and fullerene, and their derivatives or mixtures.

In the organic thin film transistor of the invention, an organic semiconductor material for an organic semiconductor layer 7 is preferably an oligomer having an average molecular weight of 5,000 or less, and as an oligomer preferably used in the invention, there is mentioned a thiophene oligomer.

The thiophene oligomer preferably used in the invention is a thiophene oligomer which contains two or more continuous substituted thiophene ring repeating units and two or more continuous unsubstituted thiophene ring repeating units, and has a total thiophene ring number of from 8 to 40. The total thiophene ring number of the thiophene oligomer is preferably from 8 to 20.

In the invention, the thiophene oligomer is preferably a compound comprising a partial structure represented by the following Formula (A).

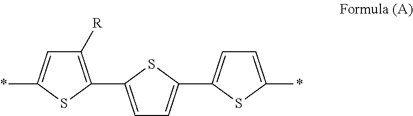

In Formula above, R represents a substituent.

Examples of the substituent represented by R in formula (1) include an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, or a pentadecyl group), a cycloalkyl group (for example, a cyclopentyl group or a cyclohexyl group), an alkenyl group (for example, a vinyl group or an allyl group), an alkynyl group (for example, an ethynyl group or a propargyl group), an aryl group (for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, or a biphenyl group), an aromatic heterocyclic group (for example, a furyl group, a thienyl group, a pyridyl group, a pyridazyl group, a pyrimidyl group, a pyrazyl group, a triazyl group, an imidazolyl group, a pyrazolyl group, a thiazolyl group, a benzimidazolyl group, a benzoxazolyl group, a quinazolyl group, or a phthalazyl group), a heterocyclic group (for example, a pyrrolidyl group, an imidazolydyl group, a morpholyl group, or an oxazolydyl group), an alkoxy group (for example, a methoxy group, an ethoxy group, a propyloxy group, a pentyloxy group, a hexyloxy group, an octyloxy group, or a dodecyloxy group), a cycloalkoxy group (for example, a cyclopentyloxy group or a cyclohexyloxy group), an aryloxy group (for example, a phenoxy group or a naphthyloxy group), an alkylthio group (for example, a methylthio group, an ethylthio group, a propylthio group, a pentylthio group, a hexylthio group, an octylthio group, or a dodecylthio group), a cycloalkylthio group (for example, a cyclopentylthio group or a cyclohexylthio group), an arylthio group (for example, a phenylthio group or a naphthylthio group), an alkoxycarbonyl group (for example, a methyloxycarbonyl group, an ethyloxycarbonyl group, a butyloxycarbonyl group, an octyloxycarbonyl group, or a dodecyloxycarbonyl group), an aryloxycarbonyl group (for example, a phenyloxycarbonyl group or a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, or a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, or a pyridylcarbonyl group), an acyloxy group (for example, an acetyloxy group, an ethylcarbonyloxy group, a butylcarbonyloxy group, an octylcarbonyloxy group, a dodecylcarbonyloxy group, or a phenylcarbonyloxy group), an amide group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, or a naphthylcarbonylamino group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, or a 2-pyridylaminocarbonyl group), a ureide group (for example, a methylureide group, an ethylureide group, a pentylureide group, a cyclohexylureide group, an octylureide group, a dodecylureide group, a phenylureide group, a naphthylureide group, or a 2-pyridylaminoureide group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, or a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, or a dodecylsulfonyl group), an arylsulfonyl group (for example, a phenylsulfonyl group, a naphthylsulfonyl group, or a 2-pyridylsulfonyl group), an amino group (for example, an amino group, an ethylamino group, a dimethylamino group, a butylamino group, a cyclopentylamino group, a 2-ethylhexylamino group, a dodecylamino group, an anilino group, a naphthylamino group, or a 2-pyridylamino group), a halogen atom (for example, a fluorine atom, a chlorine atom, or a bromine atom), a fluorinated hydrocarbon group (for example, a fluoromethyl group, a trifluoromethyl group, a pentafluoroethyl group), a cyano group, and a silyl group (for example, a trimethylsilyl group, a triisopropylsilyl group, a triphenylsilyl group, or a phenyldiethylsilyl group).

These substituents may further be substituted with the above substituents, and a plurality of the above substituents may combine with each other to form a ring. Of these, the preferred substituent is an alkyl group, the more preferred one is an alkyl group having 2 to 20 carbon atoms, and the most preferred one is an alkyl group having 6 to 12 carbon atoms.

It is preferable that the terminal group of the thiophene oligomers employed in the present invention has no thienyl group. Listed as preferred groups in the above terminal group are an aryl group (for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenylyl group); an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, and a pentadecyl group); and a halogen atom (for example, a fluorine atom, a chlorine atom, and a bromine atom).

Typical examples of the compound comprising a partial structure represented by formula (1) include exemplified compounds <1> through <22> as disclosed in Japanese Patent O.P.I. Publication No. 2006-216654.

The organic semiconductor layer 7 may be subjected to a so-called doping treatment which incorporates materials working as an acceptor which accepts electrons, for example, acrylic acid, acetamide, materials having a functional group such as a dimethylamino group, a cyano group, a carboxyl group and a nitro group, benzoquinone derivatives, or tetracyanoethylene, tetracyanoquinodimethane or their derivatives, or materials working as a donor which donates electrons, for example, materials having a functional group such as an amino group, a triphenyl group, an alkyl group, a hydroxyl group, an alkoxy group, and a phenyl group; substituted amines such as phenylenediamine; anthracene, benzoanthracene, substituted benzoanthracenes, pyrene, substituted pyrene, carbazole and its derivatives, and tetrathiafulvalene and its derivatives.

The doping herein means that an electron accepting molecule (acceptor) or an electron donating molecule (donor) is incorporated in the organic semiconductor layer as a dopant. Accordingly, the layer, which has been subjected to doping, is one which comprises the condensed polycyclic aromatic compounds and the dopant. As the dopant in the used present invention, a known dopant can be used

The organic semiconductor layer 7 can be formed via methods known in the art, including, for example, vacuum deposition, CVD (Chemical Vapor Deposition), laser deposition, electron beam deposition, a spin coating method, a dip coating method, a bar coating method, a die coating method, and a spray coating method, as well as methods such as screen printing, ink-jet printing and blade coating.

As patterning of the organic semiconductor layer, there are mentioned patterning through a mask according to a deposition method, patterning in which an organic semiconductor layer formed over whole area is subjected to photolithographic treatment and direct patterning such as an ink jet printing method.

The thickness of the organic semiconductor layer 7 is not specifically limited. Properties of the obtained transistor tend to depend significantly on the thickness of the organic semiconductor layer. The thickness is ordinarily at most 1 μm, and preferably from 10 to 300 nm, although it is different depending on kinds of the organic semiconductor.

The passivation layer 8 or 9 may be composed only of an organic layer or only of an inorganic layer. The passivation layer is preferably composed of a lamination layer of an organic layer and an inorganic layer. Materials usable for the organic layer are preferably those having no adverse effect on the organic semiconductor. Examples thereof include polyvinyl alcohol, polyvinyl pyrrolidone, and a homopolymer or a copolymer composed of a component such as HEMA, acrylic acid or acrylamide.

Employing an aqueous solution containing these materials, the organic layer can be formed according to a coating method such as a spray coating method, a spin coating method, a blade coating method or a dip coating method or a patterning method such as a printing method or an ink-jet method.

Employing inorganic oxides or nitrides such as silicon dioxide, silicon nitride, aluminum oxide, tantalum oxide, and titanium oxide, the inorganic layer can be formed according to an atmospheric pressure plasma method, a vacuum deposition method, a molecular beam epitaxial growth method, an ion cluster beam method, a low energy ion beam method, an ion plating method, a CVD method, and a sputtering method; a coating method such as a spray coating method, a spin coating method, a blade coating method or a dip coating method; or a patterning method such as a printing method or an ink-jet method.

### EXAMPLES

Next, the present invention will be explained employing examples, but is not specifically limited thereto. In the examples, the terms “parts” and “%” are used, and the terms “parts” and “%” represents “parts by mass” and “% by mass”, respectively, unless otherwise specified.

### Example 1

### <<Preparation of Sample 1-1>>

### (Preparation of Substrate 1-1)

A PET substrate was subjected to corona discharge treatment, then immersed in an aqueous 2% by mass octadecyltriethoxysilane (ODS) solution at room temperature for 10 minutes, and dried at 120° C. for 30 minutes. Thus, Substrate 1-1 was prepared.

(Preparation of Conductive Pattern)

Substrate 1-1 was brought into close contact with a chromium quartz glass photo-mask having a wiring pattern of L/S=10 μm/10 μm and exposed through the photo-mask for 10 minutes, employing a high pressure mercury lamp having absorption maximum wavelength of 365 nm. The resulting substrate was immersed in a Pd catalyst solution, dried, immersed in an electroless copper plating solution, and dried. Thus, Sample 1-1 was prepared.

### <<Preparation of Sample 1-2>>

### (Preparation of Conductive Pattern)

Substrate 1-1 prepared in Sample 1-1 was brought into close contact with a chromium quartz glass photo-mask having a wiring pattern of L/S=10 μm/10 μm and exposed through the photo-mask for 10 minutes, employing a low pressure mercury lamp having absorption maximum wavelength of 254 nm. The resulting substrate was immersed in a Pd catalyst solution, dried, immersed in an electroless copper plating solution, and dried. Thus, Sample 1-2 was prepared.

### <<Preparation of Sample 1-3>>

### (Preparation of Substrate 1-3)

A PET substrate was subjected to corona discharge treatment, then immersed in an aqueous 2% by mass octadecyltriethoxysilane solution at room temperature for 10 minutes, and dried at 120° C. for 30 minutes. Thus, Substrate 1-3b was prepared.

An isopropyl alcohol/toluene mixture solution containing 5% by mass of Sensitizing dye (25) and 1% by mass of polyvinyl alcohol was applied onto the surface of Substrate 1-3b according to a spin coat method to obtain a dry thickness of 10 nm and dried at 80° C. to evaporate the solvent. Thus, Substrate 1-3 was prepared.

(Preparation of Conductive Pattern)

Sample 1-3 was prepared in the same manner as Sample 1-1, except that Substrate 1-3 was employed.

<<Preparation of Sample 1-4>>

### (Preparation of Substrate 1-4)

A PET substrate was subjected to corona discharge treatment, then immersed in an aqueous solution containing 2% by mass of Compound A-1 at room temperature for 10 minutes, and dried at 120° C. for 30 minutes. Thus, Substrate 1-4 was prepared.

(Preparation of Conductive Pattern)

Sample 1-4 was prepared in the same manner as Sample 1-1, except that Substrate 1-4 was employed.

<<Preparation of Sample 1-5>>

### (Preparation of Substrate 1-5)

A PET substrate was subjected to corona discharge treatment, then immersed in an aqueous solution containing 2% by mass of Compound A-1 at room temperature for 10 minutes, and dried at 120° C. for 30 minutes. Thus, Substrate 1-5b was prepared.

An isopropyl alcohol/toluene mixture solution containing 5% by mass of Sensitizing dye (25) and 1% by mass of polyvinyl alcohol was applied onto the surface of Substrate 1-5b according to a spin coat method to obtain a dry thickness of 10 nm and dried at 80° C. to evaporate the solvent. Thus, Substrate 1-5 was prepared.

(Preparation of Conductive Pattern)

Sample 1-5 was prepared in the same manner as Sample 1-1, except that Substrate 1-5 was employed.

<<Preparation of Sample 1-6>>

### (Preparation of Substrate 1-6)

A PET substrate was subjected to corona discharge treatment, then immersed in an aqueous solution containing 2% by mass of Compound A-1 at room temperature for 10 minutes, and dried at 120° C. for 30 minutes. Thus, Substrate 1-6b was prepared.

An isopropyl alcohol/toluene mixture solution containing 5% by mass of Sensitizing dye (34) and 1% by mass of polyvinyl alcohol was applied onto the surface of Substrate 1-6b according to a spin coat method to obtain a dry thickness of 10 nm and dried at 80° C. to evaporate the solvent. Thus, Substrate 1-6 was prepared.

(Preparation of Conductive Pattern)

Sample 1-6 was prepared in the same manner as Sample 1-1, except that Substrate 1-6 was employed.

<<Preparation of Sample 1-7>>

### (Preparation of Substrate 1-7)

A PET substrate was subjected to corona discharge treatment, then immersed in an aqueous solution containing 2% by mass of Compound A-1 at room temperature for 10 minutes, and dried at 120° C. for 30 minutes. Thus, Substrate 1-7b was prepared.

An isopropyl alcohol/toluene mixture solution containing 5% by mass of Sensitizing dye (77) and 1% by mass of polyvinyl alcohol was applied onto the surface of Substrate 1-7b according to a spin coat method to obtain a dry thickness of 10 nm and dried at 80° C. to evaporate the solvent. Thus, Substrate 1-7 was prepared.

(Preparation of Conductive Pattern)

Sample 1-7 was prepared in the same manner as Sample 1-1, except that Substrate 1-7 was employed.

<<Preparation of Sample 1-8>>

### (Preparation of Substrate 1-8)

A PET substrate was subjected to corona discharge treatment, then immersed in an aqueous solution containing 2% by mass of Compound A-1 at room temperature for 10 minutes, and dried at 120° C. for 30 minutes. Thus, Substrate 1-8b was prepared.

An isopropyl alcohol/toluene mixture solution containing 5% by mass of Sensitizing dye (83) and 1% by mass of polyvinyl alcohol was applied onto the surface of Substrate 1-8b according to a spin coat method to obtain a dry thickness of 10 nm and dried at 80° C. to evaporate the solvent. Thus, Substrate 1-8 was prepared.

(Preparation of Conductive Pattern)

Sample 1-8 was prepared in the same manner as Sample 1-1, except that Substrate 1-8 was employed.

<<Preparation of Sample 1-9>>

### (Preparation of Substrate 1-9)

A PET substrate was subjected to corona discharge treatment, then immersed in an aqueous solution containing 2% by mass of Compound A-2 at room temperature for 10 minutes, and dried at 120° C. for 30 minutes. Thus, Substrate 1-9b was prepared.

An isopropyl alcohol/toluene mixture solution containing 5% by mass of Sensitizing dye (25) and 1% by mass of polyvinyl alcohol was applied onto the surface of Substrate 1-9b according to a spin coat method to obtain a dry thickness of 10 nm and dried at 80° C. to evaporate the solvent. Thus, Substrate 1-9 was prepared.

(Preparation of Conductive Pattern)

Sample 1-9 was prepared in the same manner as Sample 1-1, except that Substrate 1-9 was employed.

<<Preparation of Sample 1-10>>

### (Preparation of Substrate 1-10)

A PET substrate was subjected to corona discharge treatment, then immersed in an aqueous solution containing 2% by mass of Compound A-3 at room temperature for 10 minutes, and dried at 120° C. for 30 minutes. Thus, Substrate 1-10b was prepared.

An isopropyl alcohol/toluene mixture solution containing 5% by mass of Sensitizing dye (25) and 1% by mass of polyvinyl alcohol was applied onto the surface of Substrate 1-10b according to a spin coat method to obtain a dry thickness of 10 nm and dried at 80° C. to evaporate the solvent. Thus, Substrate 1-10 was prepared.

(Preparation of Conductive Pattern)

Sample 1-10 was prepared in the same manner as Sample 1-1, except that Substrate 1-10 was employed.

<<Preparation of Sample 1-11>>

### (Preparation of Substrate 1-11)

A PET substrate was subjected to corona discharge treatment, then immersed in an aqueous solution containing 2% by mass of Compound A-2 at room temperature for 10 minutes, and dried at 120° C. for 30 minutes. Thus, Substrate 1-11b was prepared.

An isopropyl alcohol/toluene mixture solution containing 5% by mass of Sensitizing dye (25), 1% by mass of polyvinyl alcohol and 1% by mass of Compound B-1 (Bis-2-(2-chlorophenyl)-4,5-diphenylimidazole) was applied onto the surface of Substrate 1-11b according to a spin coat method to obtain a dry thickness of 10 nm and dried at 80° C. to evaporate the solvent. Thus, Substrate 1-11 was prepared.

(Preparation of Conductive Pattern)

Sample 1-11 was prepared in the same manner as Sample 1-1, except that Substrate 1-11 was employed.

<<Preparation of Sample 1-12>>

### (Preparation of Substrate 1-12)

A PET substrate was subjected to corona discharge treatment, then immersed in an aqueous solution containing 2% by mass of Compound A-2 at room temperature for 10 minutes, and dried at 120° C. for 30 minutes to evaporate the solvent. Thus, Substrate 1-12b was prepared.

An isopropyl alcohol/toluene mixture solution containing 5% by mass of Sensitizing dye (25), 1% by mass of polyvinyl alcohol and 1% by mass of Compound B-2 (Irugacure 784) was applied onto the surface of Substrate 1-12b according to a spin coat method to obtain a dry thickness of 10 nm and dried at 80° C. Thus, Substrate 1-12 was prepared.

(Preparation of Conductive Pattern)

Sample 1-12 was prepared in the same manner as Sample 1-1, except that Substrate 1-12 was employed.

<<Evaluation of Samples>>

### (Evaluation of Adhesion)

The cellophane tape (“CT 24” Produced by Nichiban Co., Ltd.) was adhered to the surface of each sample with fingers, and then peeled quickly from the surface. The area rate of conductive pattern peeled together with the tape was determined, and adhesion was evaluated according to the following criteria.

A: There is no conductive pattern peeled away (which corresponds to an evaluation result of 0).

B: The area of conductive pattern peeled away is from more than 0% to 1.0%.

C: The area of conductive pattern peeled away is from more than 1.0% to 5.0%.

D: The area of conductive pattern peeled away is more than 5.0%.

(Evaluation of Thin Line Reproducibility)

The surface of each sample was observed employing a microscope VHX-600 produced by Keyence Co., Ltd., and thin line reproducibility was evaluated according to the following criteria.

A: The line width and space between lines are reproduced with an accuracy of ±10%.

B: The line width and space between lines are reproduced with an accuracy of ±20%.

C: The line width and space between lines are reproduced with an accuracy of ±50%.

D: The reproduction accuracy of the line width and space between lines fall outside the range of ±50%.

The constitution and evaluation results of each sample obtained above are shown in Table 1.

TABLE 1

| | Substrate Constitution | | | | | |
|---|---|---|---|---|---|---|
| | | | Sensitizing Dye Layer | | | |
| Sample | | Silane Coupling | Compound | Absorption Maximum | Polymerization | |
| No. | No. | Agent Processing | No. | Wavelength | Initiator | Remarks |
| 1-1 | 1-1 | ODS | None | — | None | Comp. |
| 1-2 | 1-2 | ODS | None | — | None | Comp. |
| 1-3 | 1-3 | ODS | (25) | 395 nm | None | Comp. |
| 1-4 | 1-4 | A-1 | None | — | None | Comp. |
| 1-5 | 1-5 | A-1 | (25) | 395 nm | None | Inv. |
| 1-6 | 1-6 | A-1 | (34) | 365 nm | None | Inv. |
| 1-7 | 1-7 | A-1 | (77) | 374 nm | None | Inv. |
| 1-8 | 1-8 | A-1 | (83) | 649 nm | None | Inv. |
| 1-9 | 1-9 | A-2 | (25) | 395 nm | None | Inv. |
| 1-10 | 1-10 | A-3 | (25) | 395 nm | None | Inv. |
| 1-11 | 1-11 | A-2 | (25) | 395 nm | B-1 | Inv. |
| 1-12 | 1-12 | A-2 | (25) | 395 nm | B-2 | Inv. |

| | Conductive Pattern Formation Method | | | | | |
|---|---|---|---|---|---|---|
| | Exposure Device | | | Evaluation Results | | |
| Sample | Light | Absorption Maximum | Plating | Thin Line | | |
| No. | Source | Wavelength | Process | Reproducibility | Adhesion | Remarks |
| 1-1 | a) | 365 nm | c) | D | C | Comp. |
| 1-2 | b) | 254 nm | c) | B | D | Comp. |
| 1-3 | a) | 365 nm | c) | C | C | Comp. |
| 1-4 | a) | 365 nm | c) | D | B | Comp. |
| 1-5 | a) | 365 nm | c) | A | A | Inv. |
| 1-6 | a) | 365 nm | c) | A | A | Inv. |
| 1-7 | a) | 365 nm | c) | A | A | Inv. |
| 1-8 | a) | 365 nm | c) | B | A | Inv. |
| 1-9 | a) | 365 nm | c) | B | A | Inv. |
| 1-10 | a) | 365 nm | c) | B | A | Inv. |
| 1-11 | a) | 365 nm | c) | A | A | Inv. |
| 1-12 | a) | 365 nm | c) | A | A | Inv. |

Comp.: Comparative, Inv.: Inventive,
ODS: Octadecyltrimethoxysilane
Compound A-1: Triethoxysilyl-propylamino-triazine-dithiol
Compound A-2: γ-Mercaptopropyl-trimethoxysilane
Compound A-3: 3-Mercaptopropylmethyldimethoxysilane
Compound B-1: Bis-2-(2-chlorophenyl)-4,5-diphenylimidazole
Compound B-2: Irgacure 784
Comp.: Comparative, Inv.: Inventive
a) High Pressure Mercury lamp
b) Low Pressure Mercury lamp
c) Electroless Copper Plating

As is apparent from Table 1, the inventive samples excel in both adhesion and thin line reproducibility, as compared with the comparative samples.

### Example 2

### <<Preparation of Sample 2-1>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass octadecyltriethoxysilane solution at room temperature for 10 minutes and dried at 120° C. for 30 minutes.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-1 with a source electrode 5 and a drain electrode 6 was prepared.

<<Preparation of Sample 2-2>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass octadecyltriethoxysilane solution at room temperature for 10 minutes and dried at 120° C. for 30 minutes.

The resulting base plate was exposed for 10 minutes through a chromium quartz glass photo-mask having an opening at areas where a source electrode and a drain electrode were to be formed, employing a low pressure mercury lamp having absorption maximum of 254 nm, immersed in a Pd catalyst solution, dried, immersed in an electroless copper plating solution, dried, then immersed in an electroless gold plating solution, and dried. Thus, Sample 2-2 with a source electrode 5 and a drain electrode 6 was prepared.

<<Preparation of Sample 2-3>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass octadecyltriethoxysilane solution at room temperature for 10 minutes and dried at 120° C. for 30 minutes.

Subsequently, an isopropyl alcohol/toluene mixture solution containing 5% by mass of Sensitizing dye (25) and 1% by mass of polyvinyl alcohol was applied onto the surface of the substrate according to a spin coat method to obtain a dry thickness of 10 nm and dried at 80° C. to evaporate the solvent.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-3 with a source electrode 5 and a drain electrode 6 was prepared.

<<Preparation of Sample 2-4>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass octadecyltriethoxysilane solution at room temperature for 10 minutes and dried at 120° C. for 30 minutes.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-4 with a source electrode 5 and a drain electrode 6 was prepared.

<<Preparation of Sample 2-5>>

A layer of an aluminum-neodymium (ANd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass Compound A-1 solution at room temperature for 10 minutes, and dried at 120° C. for 30 minutes.

Subsequently, an isopropyl alcohol/toluene mixture solution containing 5% by mass of Sensitizing dye (25) and 1% by mass of polyvinyl alcohol was applied onto the surface of the substrate according to a spin coat method to obtain a dry thickness of 10 nm and dried at 80° C. to evaporate the solvent.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-5 with a source electrode 5 and a drain electrode 6 was prepared.

<<Preparation of Sample 2-6>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass Compound A-1 solution at room temperature for 10 minutes, and dried at 120° C. for 30 minutes.

Subsequently, an isopropyl alcohol/toluene mixture solution containing 5% by mass of Sensitizing dye (34) and 1% by mass of polyvinyl alcohol was applied onto the surface of the substrate according to a spin coat method to obtain a dry thickness of 10 nm and dried at 80° C. to evaporate the solvent.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-6 with a source electrode 5 and a drain electrode 6 was prepared.

<<Preparation of Sample 2-7>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass Compound A-1 solution at room temperature for 10 minutes, and dried at 120° C. for 30 minutes.

Subsequently, an isopropyl alcohol/toluene mixture solution containing 5% by mass of Sensitizing dye (77) and 1% by mass of polyvinyl alcohol was applied onto the surface of the substrate according to a spin coat method to obtain a dry thickness of 10 nm and dried at 80° C. to evaporate the solvent.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-7 with a source electrode 5 and a drain electrode 6 was prepared.

<<Preparation of Sample 2-8>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass Compound A-1 solution at room temperature for 10 minutes, and dried at 120° C. for 30 minutes.

Subsequently, an isopropyl alcohol/toluene mixture solution containing 5% by mass of Sensitizing dye (83) and 1% by mass of polyvinyl alcohol was applied onto the surface of the substrate according to a spin coat method to obtain a dry thickness of 10 nm and dried at 80° C. to evaporate the solvent.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-8 with a source electrode 5 and a drain electrode 6 was prepared.

<<Preparation of Sample 2-9>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass Compound A-2 solution at room temperature for 10 minutes, and dried at 120° C. for 30 minutes.

Subsequently, an isopropyl alcohol/toluene mixture solution containing 5% by mass of Sensitizing dye (25) and 1% by mass of polyvinyl alcohol was applied onto the surface of the substrate according to a spin coat method to obtain a dry thickness of 10 nm and dried at 80° C. to evaporate the solvent.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-9 with a source electrode 5 and a drain electrode 6 was prepared.

<<Preparation of Sample 2-10>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass Compound A-3 solution at room temperature for 10 minutes, and dried at 120° C. for 30 minutes.

Subsequently, an isopropyl alcohol/toluene mixture solution containing 5% by mass of Sensitizing dye (25) and 1% by mass of polyvinyl alcohol was applied onto the surface of the substrate according to a spin coat method to obtain a dry thickness of 10 nm and dried at 80° C. to evaporate the solvent.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-10 with a source electrode 5 and a drain electrode 6 was prepared.

<<Preparation of Sample 2-11>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass Compound A-2 solution at room temperature for 10 minutes, and dried at 120° C. for 30 minutes.

Subsequently, an isopropyl alcohol/toluene mixture solution containing 5% by mass of Sensitizing dye (25), 1% by mass of polyvinyl alcohol and 1% by mass of Compound B-1 was applied onto the surface of the substrate according to a spin coat method to obtain a dry thickness of 10 nm and dried at 80° C. to evaporate the solvent.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-11 with a source electrode 5 and a drain electrode 6 was prepared.

<<Preparation of Sample 2-12>>

A layer of an aluminum-neodymium (AlNd) as an aluminum alloy was formed on a glass base plate 1 employing a sputtering method to give a thickness of 150 nm. The AlNd layer was subjected to photolithography treatment and etching treatment to form a gate electrode 2 and a contact electrode 3. Subsequently, a SiO₂ layer with a thickness of 300 nm was formed employing a plasma CVD method, whereby a gate insulation layer 4 was formed.

After the surface of the gate insulation layer 4 was subjected to UV ozone treatment, the whole base plate was immersed in an aqueous 2% by mass Compound A-2 solution at room temperature for 10 minutes, and dried at 120° C. for 30 minutes.

Subsequently, an isopropyl alcohol/toluene mixture solution containing 5% by mass of Sensitizing dye (25), 1% by mass of polyvinyl alcohol and 1% by mass of Compound B-2 was applied onto the surface of the substrate according to a spin coat method to obtain a dry thickness of 10 nm and dried at 80° C. to evaporate the solvent.

The resulting base plate was exposed for 10 minutes through a chromium quartz glass photo-mask having an opening at areas where a source electrode and a drain electrode were to be formed, employing a high pressure mercury lamp having absorption maximum of 365 nm, immersed in a Pd catalyst solution, dried, immersed in an electroless copper plating solution, dried, then immersed in an electroless gold plating solution, and dried. Thus, Sample 2-12 with a source electrode 5 and a drain electrode 6 was prepared.

<<Evaluation of Samples>>

### (Evaluation of Adhesion)

The cellophane tape (“CT 24” Produced by Nichiban Co., Ltd.) was adhered to the surface of each sample with fingers, and then peeled quickly from the surface. The area rate of source and drain electrodes peeled together with the tape was determined, and adhesion was evaluated according to the following criteria.

A: There is no conductive pattern peeled away (which corresponds to an evaluation result of 0).

B: The area of conductive pattern peeled away is from more than 0% to 1.0%.

C: The area of conductive pattern peeled away is from more than 1.0% to 5.0%.

D: The area of conductive pattern peeled away is more than 5.0%.

(Evaluation of Thin Line Reproducibility)

The surface of each sample was observed, employing a microscope VHX-600 produced by Keyence Co., Ltd., and thin line reproducibility was evaluated according to the following criteria.

A: The line width and space between lines are reproduced with an accuracy of ±10%.

B: The line width and space between lines are reproduced with an accuracy of ±20%.

C: The line width and space between lines are reproduced with an accuracy of ±50%.

D: The reproduction accuracy of the line width and space between lines fall outside the range of ±50%.

The constitution and evaluation results of each sample obtained above are shown in Table 2.

(Evaluation of Device Characteristics)

Employing each of Samples 2-1 through 2-12, an organic thin film transistor was prepared according to the following procedures.

A solution of 6,13-bistriisopropylsilylethynyl pentacene (hereinafter also referred to simply as pentacene) as an organic semiconductor material solution was applied onto the center of the source electrode 5 and the drain electrode 6 of each of Samples 2-1 through 2-12, employing an ink jet method, whereby an organic semiconductor layer 7 was formed to cover the source and drain electrodes. The applied amount of the pentacene solution was such an amount that the thickness of the dried organic semiconductor layer 7 was about 50 nm, the amount having been pre-determined according to pre-experiments.

Subsequently, a layer of PVA 124C (trade name, produced by Kuraray Co., Ltd., light insensitive polyvinyl alcohol resin) as a passivation layer 8 was formed employing a spin coating method to give a thickness of about 2 μm, and subjected to photolithography treatment and etching treatment to remove unnecessary areas, whereby the passivation layer 8 was formed.

Subsequently, a SiO₂ passivation layer 9 with a thickness of 50 nm was formed employing an atmospheric pressure plasma method.

Subsequently, a layer of PC 403 (trade name, produced by JSR Nippon Gosei Gomu Co., Ltd.,) as a light sensitive insulating layer 10 was coated on the passivation layer 9 to give a thickness of about 1 μm. The resulting material with the PC 403 layer as a resist was subjected to photolithography treatment (exposure and development), whereby a contact hole for connecting the drain electrode 6 to a pixel electrode 11 described later was formed. Specifically, the resulting material was subjected to exposure through a mask and developed to remove the PC 403 of the light sensitive insulating layer 10 of the contact hole area, and washed with water to remove the PVA 124C of the passivation layer revealed, whereby a part of the drain electrode was revealed.

Subsequently, an ITO (Indium Tin Oxide) layer for a pixel electrode 11 was deposited at a thickness of 150 nm according to a sputtering method, and subjected to photolithography treatment and etching treatment, whereby a contact electrode 3 and a pixel electrode (not illustrated) were formed. Thus, organic thin film transistors were prepared.

It has proved that the organic thin film transistors prepared above in this example, operated according to a conventional method, provide operation with a good switching property.

A: The ON/OFF ratio was 10⁵ or more.

B: The ON/OFF ratio was in the range of from 10³ to less than 10⁵.

C: The ON/OFF ratio was less than 10³.

D: No operation was carried out.

The constitution and evaluation results of each sample obtained above are shown in Table 2.

TABLE 2

| | Substrate Constitution | | | | |
|---|---|---|---|---|---|
| | | Sensitizing Dye Layer | | | |
| | Silane Coupling | | Absorption | | |
| Sample | Agent | Compound | Maximum | Polymerization | |
| No. | Processing | No. | Wavelength | Initiator | Remarks |
| 2-1 | ODS | None | — | None | Comp. |
| 2-2 | ODS | None | — | None | Comp. |
| 2-3 | ODS | (25) | 395 nm | None | Comp. |
| 2-4 | A-1 | None | — | None | Comp. |
| 2-5 | A-1 | (25) | 395 nm | None | Inv. |
| 2-6 | A-1 | (34) | 365 nm | None | Inv. |
| 2-7 | A-1 | (77) | 374 nm | None | Inv. |
| 2-8 | A-1 | (83) | 649 nm | None | Inv. |
| 2-9 | A-2 | (25) | 395 nm | None | Inv. |
| 2-10 | A-3 | (25) | 395 nm | None | Inv. |
| 2-11 | A-2 | (25) | 395 nm | B-1 | Inv. |
| 2-12 | A-2 | (25) | 395 nm | B-2 | Inv. |

| | Conductive Pattern | | | | | | |
|---|---|---|---|---|---|---|---|
| | Formation Method | | | | | | |
| | Exposure Device | | | | | | |
| | | Absorption | | Evaluation Results | | | |
| Sample | Light | Maximum | Plating | Thin Line | | Device | |
| No. | Source | Wavelength | Process | Reproducibility | Adhesion | Characteristics | Remarks |
| 2-1 | a) | 365 nm | c) | D | C | D | Comp. |
| 2-2 | b) | 254 nm | c) | B | D | D | Comp. |
| 2-3 | a) | 365 nm | c) | C | C | D | Comp. |
| 2-4 | a) | 365 nm | c) | D | B | D | Comp. |
| 2-5 | a) | 365 nm | c) | A | A | A | Inv. |
| 2-6 | a) | 365 nm | c) | A | A | A | Inv. |
| 2-7 | a) | 365 nm | c) | A | A | A | Inv. |
| 2-8 | a) | 365 nm | c) | B | A | B | Inv. |
| 2-9 | a) | 365 nm | c) | B | A | B | Inv. |
| 2-10 | a) | 365 nm | c) | B | A | B | Inv. |
| 2-11 | a) | 365 nm | c) | A | A | A | Inv. |
| 2-12 | a) | 365 nm | c) | A | A | A | Inv. |

Comp.: Comparative,
Inv.: Inventive
ODS: Octadecyltrimethoxysilane
Compound A-1: Triethoxysilyl-propylamino-triazine-dithiol
Compound A-2: γ-Mercaptopropyl-trimethoxysilane
Compound A-3: 3-Mercaptopropylmethyldimethoxysilane
Compound B-1: Bis-2-(2-chlorophenyl)-4,5-diphenylimidazole
Compound B-2: Irgacure 784
a) High Pressure Mercury lamp
b) Low Pressure Mercury lamp
c) Electroless Copper Plating and Gold Plating

As is apparent from Table 2, the inventive samples excel in both adhesion and thin line reproducibility, and in device characteristics, as compared with comparative samples.

### EXPLANATION OF THE SYMBOLS

TFT: Organic Thin Film Transistor
1: Base plate
2: Gate electrode
3: Contact electrode
4: Gate insulation layer
5: Source electrode
6: Drain electrode
7: Organic semiconductor layer
8,9: Passivation layer
10: Light sensitive insulation layer

1. A substrate having a sensitizing dye and a compound represented by the following formula (I):
(R)ₙ—Si(A)₃₋ₙ-(B) Formula (I)
wherein R represents an alkyl group having a carbon atom number of not more than 8; A represents an alkoxy group or a halogen atom; B represents a substituent containing an SH group; and n is an integer of from 0 to 2.

2. The substrate of claim 1, wherein the compound represented by formula (I) above has a triazine ring.

3. The substrate of claim 1, wherein an absorption maximum wavelength of the sensitizing dye is from 300 to 600 nm.

4. The substrate of claim 1, the substrate having a first layer and a second layer, wherein the first layer contains the sensitizing dye and the second layer contains the compound represented by formula (I).

5. The substrate of claim 4, wherein the first layer further contains a polymerization initiator.

6. The substrate of claim 4, wherein the first layer further contains a binder polymer.

7.-13. (canceled)

14. A process for forming a conductive pattern, the process comprising the steps of:
exposing a substrate to light; and
subjecting the exposed substrate to plating treatment to form a conductive pattern,
wherein the substrate has a sensitizing dye and a compound represented by the following formula (I):
(R)ₙ—Si(A)₃₋ₙ-(B) Formula (I)
wherein R represents an alkyl group having a carbon atom number of not more than 8; A represents an alkoxy group or a halogen atom; B represents a substituent containing an SH group; and n is an integer of from 0 to 2.

15. The process for forming a conductive pattern of claim 14, wherein the light at the exposing step has a main wavelength in a range of from 300 to 600 nm.

16. The process for forming a conductive pattern of claim 14, wherein a high pressure mercury lamp is employed at the exposing step.

17. The process for forming a conductive pattern of claim 14, wherein the plating treatment comprises providing a catalyst on the exposed substrate, followed by an electroless plating treatment.

18. An organic thin film transistor comprising a substrate and a conductive pattern, wherein the substrate has a sensitizing dye and a compound represented by the following formula (I):
(R)ₙ—Si(A)₃₋ₙ-(B) Formula (I)
wherein R represents an alkyl group having a carbon atom number of not more than 8; A represents an alkoxy group or a halogen atom; B represents a substituent containing an SH group; and n is an integer of from 0 to 2.

19. The organic thin film transistor of claim 18, wherein the conductive pattern is formed employing the process for forming a conductive pattern of claim 14.

20. The organic thin film transistor of claim 18, wherein the conductive pattern is a source electrode or a drain electrode.
